(19) United States
(12) Patent Application Publication
(10) Pub. No.: US 2025/0385741 A1
(43) Pub. Date: Dec. 18, 2025

(54) IMPEDANCE CALIBRATION METHOD OF RADIO FREQUENCY TRANSMITTER AND ASSOCIATED ELECTRONIC DEVICE

(71) Applicant: Realtek Semiconductor Corp., HsinChu (TW)

(72) Inventors: Chia-Wei Huang, HsinChu (TW); Yi-Hua Lu, HsinChu (TW)

(21) Appl. No.: 19/231,601

(22) Filed: Jun. 9, 2025

(30) Foreign Application Priority Data
Jun. 17, 2024 (TW) 113122320

(51) Int. Cl. H04B 17/13; H03F 3/24

(52) U.S. Cl. CPC H04B 17/13; H03F 3/245; H03F 2200/451

(57) ABSTRACT

The present invention provides an impedance calibration method of a RF transmitter, wherein the impedance calibration method includes the steps of: (a) generating a two-tone test signal to the RF transmitter to generate a RF signal; (b) calculating a IMD3 according to the RF signal; (c) calculating a IMD3 difference between the IMD3 and a default IMD3; and (d) if the IMD3 difference is not less than a threshold value, tuning an impedance of the RF transmitter, and repeating step (b) and step (c), until the IMD3 difference is less than the threshold value.

### BACKGROUND OF THE INVENTION

### 1. Field of the Invention

The present invention relates to a radio frequency (RF) transmitter of an electronic device.

### 2. Description of the Prior Art

In a current RF transmitter, a power amplifier is usually provided to achieve high power output. When designing a power amplifier, a maximum saturation output power (Psat) is usually considered to obtain an optimal load impedance (Zopt), and then the optimal load impedance is matched to 50 ohms during the internal design of the chip. However, since the power amplifier in the RF transmitter needs to operate in a linear-active region in actual applications, the optimal impedance for the gain of the RF transmitter may greatly deviate from 50 ohms, making the gain and linearity be easily affected by impedance changes. Specifically, after the RF transmitter is connected to the antenna, the impedance of the antenna will cause the load of the RF transmitter to change, which will affect the power and error vector magnitude (EVM) of the RF transmitter.

### SUMMARY OF THE INVENTION

Therefore, one of the objects of the present invention is to provide a RF transmitter and related impedance calibration method, which can improve the power and EVM of the RF transmitter to solve the problems described in the prior art.

According to one embodiment of the present invention, an impedance calibration method of a RF transmitter comprises the steps of: (a) generating a two-tone test signal to the RF transmitter to generate a RF signal; (b) calculating a IMD3 according to the RF signal; (c) calculating a IMD3 difference between the IMD3 and a default IMD3; and (d) if the IMD3 difference is not less than a threshold value, tuning an impedance of the RF transmitter, and repeating step (b) and step (c), until the IMD3 difference is less than the threshold value.

According to one embodiment of the present invention, an electronic device is disclosed. The electronic device comprises a baseband circuit, a RF transmitter, a feedback circuit, a IMD3 calculation circuit and an impedance tuner circuit. The baseband circuit is configured to generate a two-tone test signal. The RF transmitter is configured to generate a RF signal according to the two-tone test signal. The feedback circuit is configured to generate a PSD according to the RF signal, wherein the PSD comprises a baseband component and a third-order intermodulation component. The IMD3 calculation circuit is configured to calculate a IMD3 according to the PSD, and to calculate a IMD3 difference between the IMD3 and a default IMD3. If the IMD3 difference is not less than a threshold value, the impedance tuner circuit tunes an impedance of the RF transmitter, until the IMD3 difference is less than the threshold value.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an electronic device according to one embodiment of the present invention.

FIG. 2 is a diagram illustrating a RF transmitter according to one embodiment of the present invention.

FIG. 3 is a flowchart of an impedance calibration method of the RF transmitter according to one embodiment of the present invention.

### DETAILED DESCRIPTION

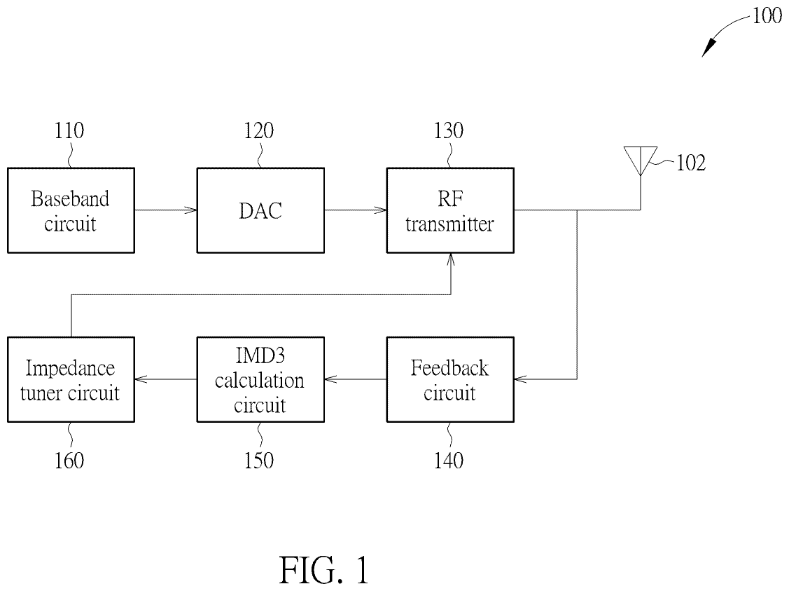

FIG. 1 is a diagram illustrating an electronic device 100 according to one embodiment of the present invention. As shown in FIG. 1, the electronic device 100 comprises a baseband circuit 110, a digital-to-analog converter (DAC) 120, an RF transmitter 130, a feedback circuit 140, a third-order intermodulation distortion (IMD3) calculation circuit 150, an impedance tuner circuit 160 and an antenna 102. In this embodiment, the electronic device 100 can be any electronic device with wireless communication functions, such as a notebook computer, a smart phone, a tablet computer, etc.

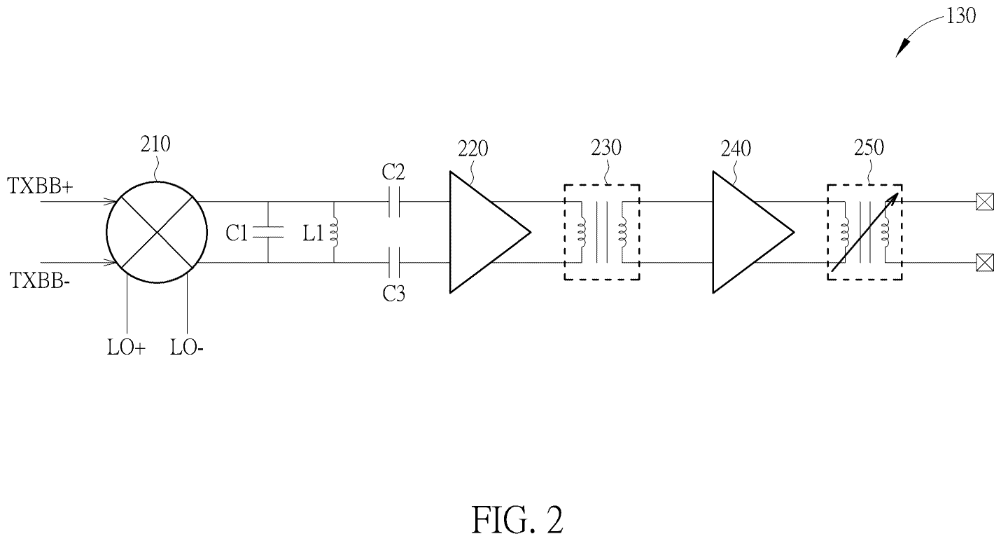

FIG. 2 is a diagram illustrating the RF transmitter 130 according to one embodiment of the present invention. As shown in FIG. 2, the RF transmitter 130 comprises a mixer 210, a driver stage power amplifier 220, a transformer 230, a power amplifier 240, a tunable impedance element 250, an inductor L1 and a plurality of capacitors C1, C2 and C3. In the operation of the RF transmitter 130, the mixer 210 uses oscillation signals LO+ and LO− to perform mixing operations on baseband signals TXBB+ and TXBB− to generate a RF signal. The RF signal is processed by the inductor L1, the capacitors C1, C2 and C3, the driver stage power amplifier 220, the transformer 230 and the power amplifier 240 to generate an amplified signal. The amplified signal is then transmitted to a balanced-to-unbalanced converter at the back-end through the tunable impedance element 250, and is transmitted through the antenna 102.

In one embodiment, the RF transmitter 130 is a microwave transmitter.

It is noted that the circuit architecture of the RF transmitter 130 shown in FIG. 2 is only an example and is not a limitation of the present invention.

In other embodiments, some components in the RF transmitter 130 can be removed, for example, at least part of the inductor L1, the capacitors C1, C2 and C3, the driver stage power amplifier 220 and the transformer 230 can be removed from the RF transmitter 130. In addition, since the main operations of the RF transmitter 130 are well known to a person skilled in the art, and the focus of the present invention is how to control the impedance the tunable impedance element 250, the detailed operation details of the RF transmitter 130 will not be repeated here.

As mentioned in the prior art, since the power amplifier 240 in the RF transmitter 130 needs to operate in the linear amplification region in actual applications, the optimal impedance corresponding to the gain of the RF transmitter 130 may greatly deviate from 50 ohms, which affects the power and EVM of the RF transmitter 130. Therefore, the present invention proposes an impedance calibration method for the RF transmitter 130, which can obtain IMD3 corresponding to different impedance values by controlling the tunable impedance element 250 coupled to the output end of the power amplifier 240. Since IMD3 is positively correlated with the EVM, IMD3 can be used to determine the appropriate impedance value of the tunable impedance element 250 to improve the power and EVM of the RF transmitter 130.

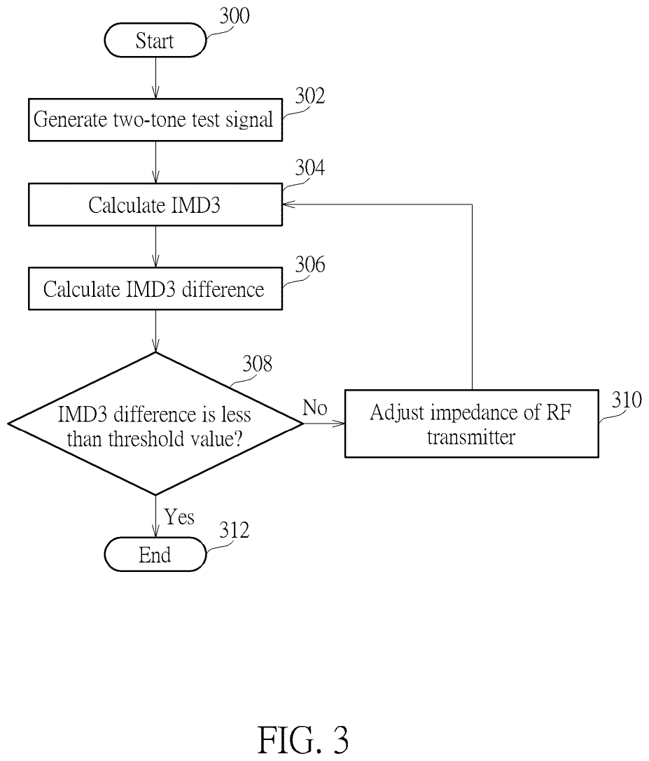

FIG. 3 is a flowchart of an impedance calibration method of the RF transmitter 130 according to one embodiment of the present invention. In Step 300, the flow starts, and the electronic device 100 is powered on and starts an impedance calibration process. In Step 302, the baseband circuit 110 generates a two-tone test signal. In Step 304, the two-tone test signal is processed by the RF transmitter 130 to generate a RF signal, and the RF signal is used to calculate the IMD3. Specifically, the DAC 120 performs a digital-to-analog conversion operation on the two-tone test signal to generate an analog two-tone test signal as the baseband signals TXBB+ and TXBB− shown in FIG. 2. The RF transmitter 130 processes the analog two-tone test signal to generate the RF signal to the antenna 102. In addition, the feedback circuit 140 processes the RF signal to obtain a power spectral density (PSD), where the PSD comprises a baseband component and a third-order intermodulation component, and the IMD3 calculation circuit 150 IMD3 calculates the IMD3 based on the power of the baseband component and the power of the third-order intermodulation component included in the PSD. For example, assuming that the two frequencies included in the two-tone test signal are f1 and f2 (f2 is greater than f1), the PSD comprises the power of the baseband components f1 and f2, and the power of the third-order intermodulation component (2*f2−f1) and (2*f1−f2), the IMD3 calculation circuit 150 can calculate the ratio between the power of the baseband component f2 and the power of the third-order intermodulation component (2*f2−f1) to obtain the IMD3.

In Step 306, the IMD3 calculation circuit further calculates an IMD3 difference between the IMD3 obtained in Step 304 and a default IMD3, where the default IMD3 can be the IMD3 corresponding to 50 ohms in the previous design, or any IMD3 determined/tested in the previously design. The IMD3 difference can be a subtraction result between the IMD3 obtained in Step 304 and the default IMD3, or the IMD3 difference can be any value capable of representing the difference between the IMD3 obtained in Step 304 and the present IMD3

In Step 308, the impedance tuner circuit 160 determines whether the IMD3 difference is less than a threshold value, where the threshold value can be 2dBc, 3dBc or any other suitable value. If the impedance tuner circuit 160 determines that the IMD3 difference is not less than the threshold value, the flow enters Step 310; and if the impedance tuner circuit 160 determines that the IMD3 difference is less than the threshold value, the flow enters Step 312.

In Step 310, the impedance tuner circuit 160 generates a control signal to control the tunable impedance element 250 in the RF transmitter 130 to have different impedance values, and the flow goes back to Step 304 to calculate the IMD3 difference between the IMD3 obtained in Step 304 and the default IMD3, and to determine whether the IMD3 difference is less than the threshold value.

In Step 312, the flow ends. At this time, the current impedance value of the tunable impedance element 250 in the RF transmitter 130 is used as a final impedance value to be used by the RF transmitter 130 during subsequent operations of the electronic device 100.

As shown in FIG. 3, in the impedance calibration method of the RF transmitter of the present invention, if the IMD3 difference calculated based on the RF signal is not less than the threshold value, the impedance tuner circuit 160 will adjust the impedance of the RF transmitter 130, and repeat Step 304 and Step 306, until the IMD3 difference is less than the threshold value. Therefore, by using the impedance calibration of the present invention, the power and EVM of the RF transmitter 130 can be improved to solve the problems described in the prior art.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An impedance calibration method of a radio frequency (RF) transmitter, comprising:
(a) generating a two-tone test signal to the RF transmitter to generate a RF signal;
(b) calculating a third-order intermodulation distortion (IMD3) according to the RF signal;
(c) calculating a IMD3 difference between the IMD3 and a default IMD3; and
(d) if the IMD3 difference is not less than a threshold value, tuning an impedance of the RF transmitter, and repeating step (b) and step (c), until the IMD3 difference is less than the threshold value.

2. The impedance calibration method of claim 1, wherein the RF transmitter comprises a mixer, a power amplifier and a tunable impedance element, wherein the tunable impedance element is coupled to an output terminal of the power amplifier; and the step (d) comprises:
if the IMD3 difference is not less than the threshold value, tuning an impedance value of the tunable impedance element, and repeating step (b) and step (c), until the IMD3 difference is less than the threshold value.

3. The impedance calibration method of claim 2, further comprising:
(e) if the IMD3 difference is less than the threshold value, using a current impedance value of the tunable impedance element as a final impedance value to be used by the RF transmitter during subsequent operations.

4. The impedance calibration method of claim 1, wherein the IMD3 difference is a subtraction result between the IMD3 and the default IMD3.

5. The impedance calibration method of claim 1, wherein the RF transmitter is a microwave transmitter.

6. An electronic device, comprising:
a baseband circuit, configured to generate a two-tone test signal;
a radio frequency (RF) transmitter, configured to generate a RF signal according to the two-tone test signal;
a feedback circuit, configured to generate a power spectral density (PSD) according to the RF signal, wherein the PSD comprises a baseband component and a third-order intermodulation component;
a third-order intermodulation distortion (IMD3) calculation circuit, configured to calculate a IMD3 according to the PSD, and to calculate a IMD3 difference between the IMD3 and a default IMD3; and
an impedance tuner circuit, wherein if the IMD3 difference is not less than a threshold value, the impedance tuner circuit tunes an impedance of the RF transmitter, until the IMD3 difference is less than the threshold value.

7. The electronic device of claim 6, wherein the RF transmitter comprises a mixer, a power amplifier and a tunable impedance element; and if the IMD3 difference is not less than the threshold value, the impedance tuner circuit tunes an impedance value of the tunable impedance element, until the IMD3 difference is less than the threshold value.

8. The electronic device of claim 7, wherein if the IMD3 difference is less than the threshold value, the impedance tuner circuit uses a current impedance value of the tunable impedance element as a final impedance value to be used by the RF transmitter during subsequent operations.

9. The electronic device of claim 6, wherein the IMD3 difference is a subtraction result between the IMD3 and the default IMD3.

10. The electronic device of claim 6, wherein the RF transmitter is a microwave transmitter.
